(19) United States
(12) Patent Application Publication
(10) Pub. No.: US 2005/0253245 A1
(43) Pub. Date: Nov. 17, 2005

(54) Package design and method for electrically connecting die to package

(76) Inventors: Mark Lynch, Dana Point, CA (US); Seyed Hassan Hashemi, Lagunua Niguel, CA (US)

Correspondence Address: WEIDE & MILLER - MINDSPEED, 7251 WEST LAKE MEAD BLVD., SUITE 530, LAS VEGAS, NV, 89128, US

(21) Appl. No.: 10/843,946

(22) Filed: May 12, 2004

(51) Int. Cl. H01L 23/04

(52) U.S. Cl. 257/698

(57) ABSTRACT

A method and apparatus for electrically connecting a die to a package while reducing the length of wirebonds. This in turn reduces wire-sweep and the cost of manufacture. To reduce the length of the wirebonds, bonding holes are created through an insulating layer of the package to expose a conductive layer. A wirebond connects through the bonding hole to a conductive layer that is exposed by the hole. The attachment point for the wirebond on the conductive layer may be prepared to serve as a bonding pad. Using this technique the prior art method utilized a bonding pad on the top surface of the inner surface of the package, which electrically connects through a trace to a via, which in turn electrically connects to a conductive layer may be avoided thereby allowing for closer spacing of radially concentric rows of attachment points on the package around the die.

### FIELD OF THE INVENTION

The invention relates to semiconductor design and manufacture and, in particular, to a method and apparatus for package construction to enable electrical connection between a die and a package.

### RELATED ART

There exists a continuing demand for electronic devices that have greater functionality and speed. As such there has been, and continues to be, great strides in the development of new integrated circuit technologies that allow circuit designers to meet these needs. For example, electronic circuits increasingly operate at higher speeds and enjoy reductions in size as compared to circuits of a few years ago.

By way of background, an integrated circuit is often referred to as an electronic “chip” and it often comprises numerous subparts. In particular, a die or integrated circuit, which contains or comprises one or more circuits, is housed within a package that protects and secures the die. The die often comprises one or more metallic layers, one or more insulating layers, and one or more ion implanted regions. Most often, the outer top edge of the die contains numerous bonding pads to which extremely small wires (hereinafter wirebonds) attach using a process referred to as wirebonding. These wirebonds provide electrical input and output points between the package and the die.

The wirebonds electrically attach to the package and, in turn, the package electrically connects to a circuit board or other structure configured to interface with the circuit. As is commonly understood, the package comprises a protective housing or container configured with numerous leads or contact points on its outer surface that provides electrical access, via conductive layers of the package to the wirebonds and the die. The inner area of the package is created by injection molding using hot and fluid package material to thereby encapsulate the die and the wirebonds.

Via the contact points or leads, access may be gained to the circuits on the die while the die is enclosed and protected by the package housing. For example, certain packages may have numerous leads extending from the outer edge of the package while other package configurations utilize a ball grid array configuration (BGA) to provide numerous contacts or solder points on the bottom surface of the package.

As a result of the advancements in integrated circuit technology, the dies continue to grow smaller while the number of electronic devices on the integrated circuit and the number of conductors, i.e. bus width, that connect to the die increases. Consequently, it may be necessary to utilize a greater and greater number of wirebonds to electrically connect the die to the package. Thus, as the dies are designed smaller and the number of bonding pads on the die increases, the density of the wirebonds increases.

A better understanding of the various components may be gained by reference to FIG. 1. As shown, FIG. 1 illustrates a prior art package configuration. A die 104 is located on a package 108 and one or more rows of bonding pads 112 are located on the outer edge of the die 104.

The package 108 has one or more rows of conductive traces 120A, 120B, 120C, 120D at least partially surrounding the die 104. The conductive traces 120A-120D comprise electrically accessible conductors, such as deposition layers, on the surface of the inner top layer of the package 108. In this embodiment, traces 120A and 120B comprise a common electrical node, such as for a supply voltage node and a ground node, respectively.

Certain of the conductive traces, namely trace 120C and trace 120D, have trace extensions extending to a via 134. For example, a trace extends from bonding pad 150 to via 134. The via 134 connects to a lower layer of the package which is routed accordingly to either of a ball grid array or a package lead, or directly to a solder ball.

Appropriate wirebonds 130 are shown connecting between the bonding pads 104 on the die and a location on the trace 120. As can be appreciated and seen in FIG. 1, in the area 136 near the die, the density of the wirebonds 130 is high resulting in the wirebonds being located very close together.

Because of the close proximity of the wirebonds and the required flexibility of the wirebonds, during the packaging of the die the wirebonds often suffer from a phenomenon known as wire-sweep. Wire-sweep occurs when the heated, liquid package material is injected around the die and, due to the flexible wirebonds, the wirebonds slightly bend or flex thereby shorting together. This will yield the chip unusable and is a significant cause of product rejection during the manufacturing process. The likelihood of wire-sweep occurring increases as the length of the wirebonds, such as for example, wirebond 130 increases. The length of the wirebond is dependant on the distance of the bonding pads 150, 152 from the die 104. This is a drawback associated with prior art methods that utilize a design that extends the wirebond to a distant bonding pad.

Another drawback associated with this arrangement is that as the length of the wirebonds 130 increase, so to does the cost associated with the manufacturing process. Most often, the wirebonds 130 comprise gold or a gold alloy and as such, decreasing the length of the wirebonds, decreases the amount of precious metal used and the cost of each device. Another drawback associated with long wirebonds is that because electrical performance is inversely proportionally to length, longer wirebonds may lead to a reduction in performance. For example, longer wirebonds increase resistance, impedance, as well as, crosstalk with nearby wirebonds.

The method and apparatus disclosed herein overcomes the drawbacks associated with long wirebonds thereby reducing the occurrence of wire-sweep and reducing the cost of manufacture.

### SUMMARY

To overcome the drawbacks of the prior art and provide additional advantages as disclosed herein, a method for electrically connecting a die to a package is disclosed. In one embodiment this method comprises providing a package having a foundation and one or more laminated sections on the foundation to form a laminated package base. In one embodiment the laminated section comprises an insulating layer covering a conductive layer and the package further comprises at least one bonding hole through at least one insulating layer to thereby expose a conductive layer. The method also secures the die to the package and attaches a wirebond to at least one bonding pad on the die. The method then attaches the wirebond to a conductive layer accessed through a bonding hole to thereby electrically connect the die to the package.

In one embodiment this method further comprises preparing the conductive layer, exposed by the bonding hole, for bonding with a wirebond. The wirebond may comprise a gold wire. It is contemplated that the package may comprise at least one row of surface bonding pads that radially surround the die and at least one row of bonding holes that radially surround the die whereby use of bonding holes allows for bonding directly to a conductive layer thereby reducing the length of at least one wirebond. In one embodiment the step of attaching comprises pressure fusing.

Also disclosed herein is a method for configuring a package for enclosing a die comprising the steps of providing a package foundation and forming one or more conductive layers above the foundation. Then the method forms one or more insulating layers above the foundation and creates one or more bonding holes in at least one insulating layer to provide access to at least one conductive layer such that the bonding hole is configured for placement of a wirebond there-through to bond directly to the conductive layer or a bonding pad on the conductive layer.

In one embodiment this method further comprises forming at least one bonding pad on the surface of the insulating layer and forming a via to the conductive layer. This method of configuring a package then forms a conductive trace between the via and the bonding pad on the surface of the insulating layer. With regard to the bonding hole, it is contemplated that the bonding hole is sized to accept a wirebond and that creating a bonding hole may comprise drilling using a laser. In one embodiment the one or more conductive layers and the one or more insulating layers alternate between conductive and insulating layers.

Also disclosed herein is the package itself that is configured to electrically connect a die to a conductor external to the package. In this embodiment the package comprises a package foundation having one or more conductive layers and one or more insulator layers and one or more die placement locations configured to support a die. The package also comprises one or more bonding holes located proximate to at least one of the one or more die placement locations such that at least one bonding hole is configured to extend through at least one insulating layer to thereby provide access to a conductive layer. The package also comprises at least one exterior conductor on the exterior of the package that is in electrical contact with at least one conductive layer.

In one variation, the package further comprising a wirebond electrically connected to a die and a conductive layer accessed through one of the bonding holes. It is contemplated that the package may be configured as a multi-chip package configured to accommodate more than one die. In one embodiment the package comprises two insulator layers and the bonding hole passes through two insulator layers to expose a conductive layer.

Also disclosed herein is a semiconductor device configured with at least one die having one or more bonding pads configured to connect to one or more wirebonds and a package. The package comprises a package foundation, one or more conductive layers, and one or more insulating layers. It is contemplated that at least one insulating layer covers at least one conductive layer. One or more bonding holes extend through at least one insulating layer to thereby provide access to a conductive layer and at least one wirebond electrically connected to a bonding pad on the at least one die and also connected to a conductive layer accessed through a bonding hole.

In one embodiment the wirebond connects to a bonding pad prepared on the conductive layer that is accessed through the bonding hole and bonding pad may be prepared on the conductive layer using a gold deposition. In addition, in one embodiment, the device further comprises one or more solder bumps or pins electrically accessible from the exterior of the package that connect to at least one of the one or more conductive layers. In addition, a protective layer may be formed to encapsulate the die and wirebonds. In this embodiment the use of bonding holes reduces the length of at least one wirebond thereby reducing wire-sweep.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 illustrates a top plan view of an exemplary prior art die to package electrical interconnect.

FIG. 2 illustrates a cut-away side view of an example embodiment of a package configuration.

FIG. 3 illustrates a cut-away side view of a package design having one or more bonding holes established therein.

FIG. 4 illustrates a top plan view of a package configured with bonding holes.

FIG. 5 illustrates a cut-away side view of a package having a variety of wirebond bonding locations.

FIG. 6 is an operational flow diagram of an example method of package fabrication utilizing bonding holes.

### DETAILED DESCRIPTION

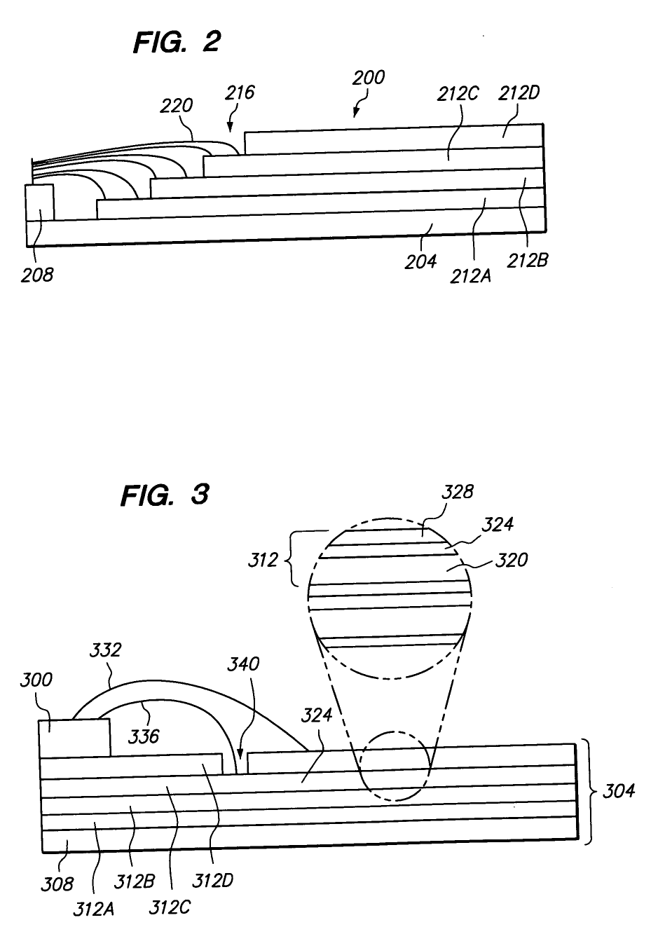

One proposed solution to the prior art problem of excessive wirebond lengths is to configure a package as shown in FIG. 2. FIG. 2 illustrates a cut-away side view of a package. As shown, a laminated package 200 is configured with a base layer 204 that supports the die 208 and one or more layers 212A, 212B, 212C, 212D that are built up over the base layer 204. The edges of the layers 212 near the die 208 are stair-stepped and the exposed step of each layer is configured with a wirebond pad 216. This arrangement is also known as wirebond tiers. The wirebonds extend from the die and connect to the bonding pads 216. The stair-stepped arrangement of the package, as shown, allows for shorter wirebonds 220 because the bonding pads 216 on the package may be placed more closely together and, due to the stair step configuration, wire-sweep is less likely.

This configuration is, however, more difficult to manufacture because, each layer 212 that is placed on the base layer 204 must be pre-configured to have the desired size and location of opening for access to the die. In one embodiment, the opening in each layer is routed and the access to the underlying layer created. The individual layers 212 must then be aligned and secured to create the configuration shown in FIG. 2. This can be a complex, time consuming, and expensive process. Furthermore, the single layer 204 which supports the die 208 may be prone to warping due to the variation in thickness of the laminated package.

FIG. 3 illustrates a cut-away side view of a package design having one or more access holes established therein. As shown in this embodiment, a die 300 secures to a portion of a laminated package 304 having a base layer 308 and one or more additional layers 312A-312D attached to the base layer. In reference to the expanded view of the layer, it is contemplated that each layer 312 may comprise a structurally supportive bottom layer 320 which supports a conductive layer 324. A protective insulating layer 328 covers the conductive layer 324. It is contemplated that the protective layer 328 and the bottom layer 320 may comprise insulating layers. This is but one possible configuration for a layer 312 and, as such, it is contemplated that in other embodiments the layers may be named or configured differently, or serve different purposes. In addition, there may exist fewer or a greater number of layers than is shown in the exemplary figure which is provided for discussion and to aid in understanding. The claims that follow are not limited to this particular layer structure or package design.

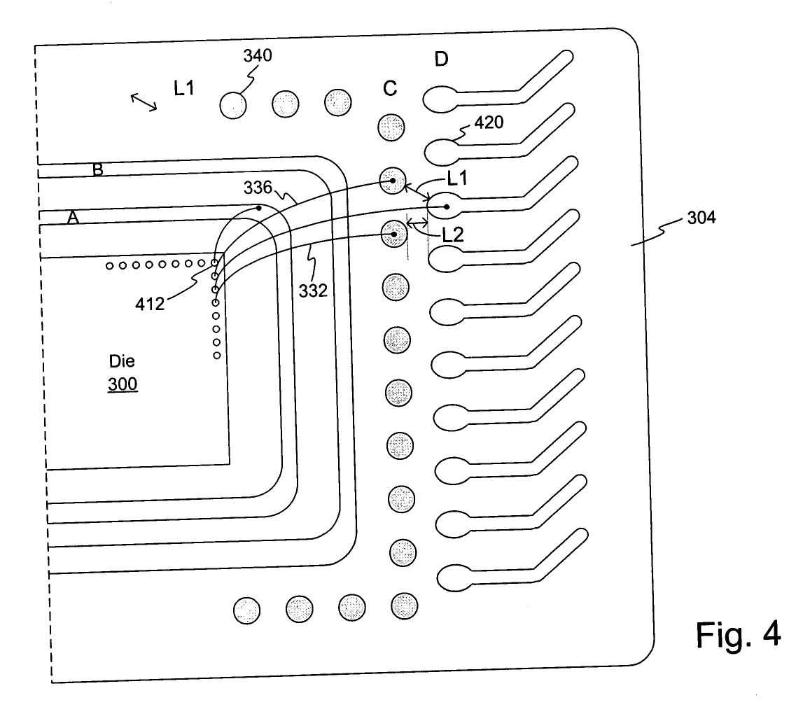

Also shown in FIG. 3 is one or more wirebonds 332, 336 that connect to the die 300, such as to a bonding pad on the die, and to the package 304. As shown, the wirebond 332 connects to the top layer 312D, such as to a bonding pad (not shown) on the top layer. The trace, not shown in this figure, may extend to another area on the top surface of the package 304. In contrast to wirebond 332 which attaches to the top layer, wirebond 336 extends into a bonding hole 340 or via that extends through one or more package layers 312. The wirebond 336 connects to the conductive layer 324 of layer 312C. This configuration provides the benefit of providing access to a conductive layer while minimizing the length of wirebonds 332, 336. It is contemplated that the bottom of the hole 340 may be configured as a bonding pad. FIG. 4, which follows, clearly illustrates the benefit gain, due to an ability to reduce wirebond length, from the configuration shown in FIGS. 3-5.

FIG. 4 illustrates a top plan view of a package configured with bonding holes. As compared to FIG. 3, identical elements are referenced with identical reference numerals. The die 300 is configured with bonding pads 412 as shown. The die 300 is secured to a package 304. It is contemplated that some of the bonding pads 412 on the die connect to a trace A or a trace B. It is further contemplated that wirebond 336 connects at a first end to a bonding pad 412 of a die while a second end of the wirebond connects to a trace 420 on the inner top surface. The trace 420 may extend to another area of the package, such as to a via that electrically connects to a ball of a ball grid array, or to a pin that extends from the package 304.

The wirebond 332 comprises a first end that attaches to and extends from a bonding pad 412 to a bonding hole 340. The bonding hole 340 extends into the package 304, such as through one or more insulating layers to a conductive layer. The wirebond thereby attaches directly to the conductive layer, a metallic layer or other layer in the bonding hole to provide electrical contact between the wirebond 332 to a conductive layer in the package. It is contemplated that the conductive layer may extend directly downward, horizontally or both and connect to a pin, solder ball or any other type connection that provides electrical access to the package 304.

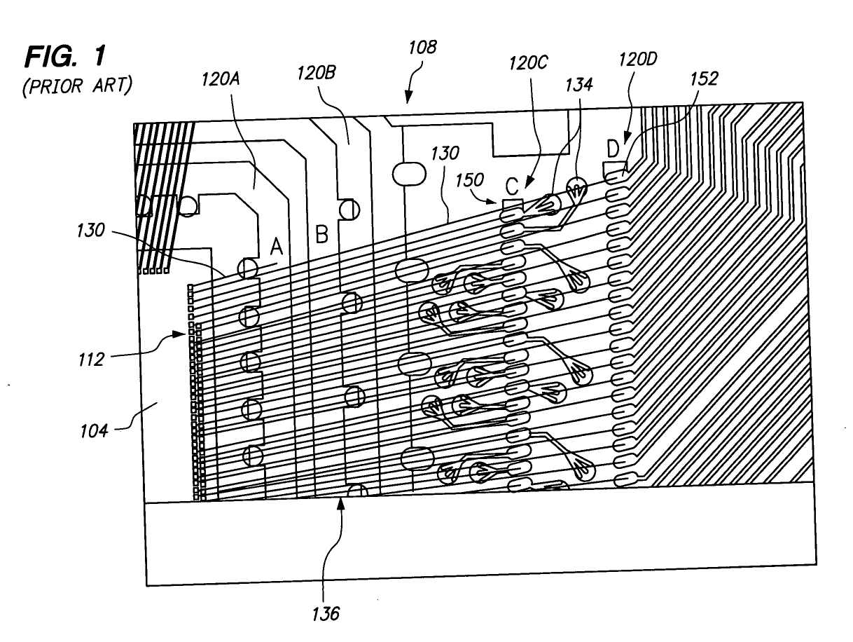

An advantage associated with the use of bonding holes 340 is that the distance L1 and L2 between trace 420 and bonding hole 340 is reduced because, as compared to FIG. 1, row D may be moved closer to row C. This occurs because use of bonding holes 340 allows for bonding directly down to a conductive layer whereas in the configuration of FIG. 1, a trace would have to be extended from the bonding pad 150 to a via 134 (see FIG. 1) where the trace would electrically connect to a lower layer. Thus, in one embodiment based on the teachings contained herein, the bonding of the wirebond occurs directly to a lower layer through a hole 340 instead of, as shown in FIG. 1, to a bonding pad on a trace, the trace then extending to a via to a lower layer.

This configuration has the advantage of allowing for closer placement to the die, of the elements in row C and the elements in row D, which in turn reduces the length of the wirebonds 332, 336. Shorter wirebonds 332, 336 are less likely to wire-sweep and as a result, the yield of usable chips is raised when using bonding holes instead of the configuration shown in FIG. 1. It is contemplated that the entire top surface, as shown in FIG. 4, would be injection filled with heated package material in liquid form, and use of shorter wirebonds substantially reduces wire-sweep.

Furthermore, reducing the length of the wirebonds 332, 336 reduces the cost of each device due to a reduction in material, namely wirebond. Over thousands, or tens of thousands of devices, each with potentially hundreds of wirebonds, the cost savings could be substantial.

Yet another advantage associated with the use of bonding holes 340 comprises the reduction in complexity during fabrication of the package. In the prior art method associated with FIG. 1, the structure responsible for electrically connecting the wirebond to the package comprises the package bonding pad 150, the trace to a via, and the via 134 to a lower package layer. In contrast, using the configuration of FIGS. 3 and 4, the wirebond 332 connects directly to a conductive layer through the hole. Thus, the only fabrication element required is the hole, which is not a complex fabrication step. Eliminated are the trace and the bonding pad on the trace. Thus, the same end result is achieved, with a reduction in elements required to achieve that result. This is in addition to the other benefits set forth herein.

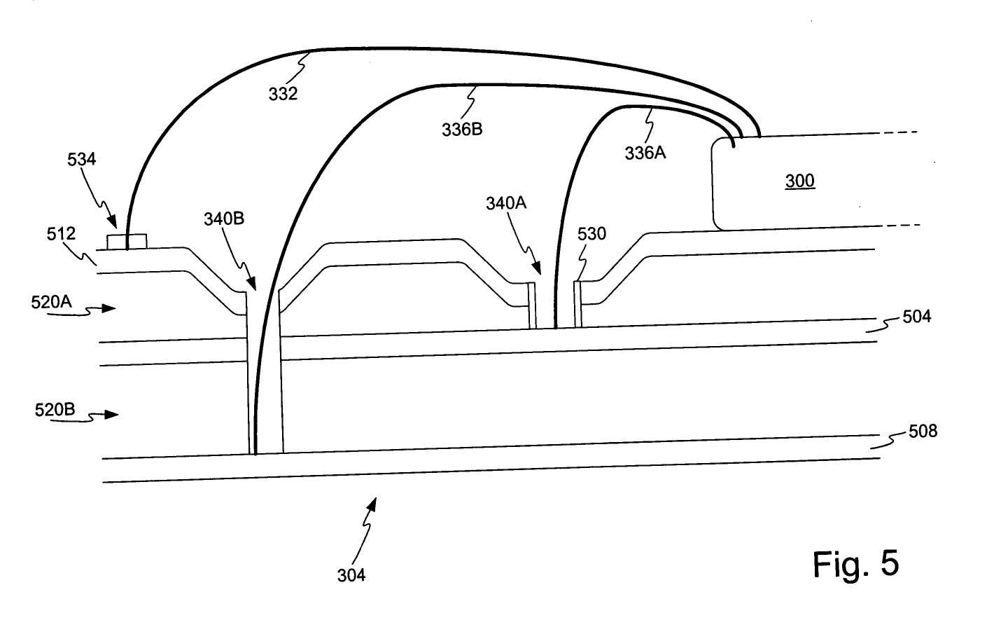

FIG. 5 illustrates a cut-away side view of a package having a variety of wirebond bonding locations. As compared to FIGS. 3 and 4, identical elements are identified with identical reference numerals. As shown, a die 300 resides on a package 304. Wirebonds 332, 336A, 336B electrically connect to and extend from the die 300 and connect to conductive layers 512, 504, 508 in or on the package 304. Insulating layers 520A and 520B separate the conductive layers to thereby maintain separation between signals on the conductive layers 512, 504, 508.

The wirebond 332 bonds directly to the upper inner surface of the package, in particular, conductive layer 512. A bonding pad 534 may be provided. Wirebond 336A connects to conductive layer 504 through a bonding hole 340A, which in turn may extend or connect to a solder ball (not shown) of a ball grid array or to a pin (not shown). A bonding hole 340 may comprise a hole, a via, a conjoined group of holes, or any other element configured to provide access to a conductive layer and thereby reduce the length of a wirebond.

Wirebond 340B extends to and into bonding hole 340B and bonds to a conductive layer 508. In this example embodiment, bonding hole 340B extends through two insulating layers 520A, 520B whereas bonding hole 340A extends through only insulating layer 520A. It is contemplated that in other embodiments the bonding holes 340 may extend through any number of layers. The holes 340 may be created by any technique now know or developed in the future, including, but not limited to, laser or mechanical drilling, chemical etching, or patterned additive layer formation. The interior of the bonding holes 340 may be covered with or coated with an insulator 530 as shown in bonding hole 340A. The insulator 530 will prevent unwanted contact of the wirebonds with the sides of hole or the top surface of the layer near the hole. In addition, a hole may be plated with conductive metal which has electrical benefit such as shielding or may be the result of the process of plating the sub-surface bond sites.

As can be appreciated, the drill down nature of the bonding holes 340 allows for closer placement of the holes in relation to the die and adjacent holes because it is no longer required to bond all wirebonds to a surface bonding pad 534 on a surface trace and then electrically extend the surface trace to a via that links to one or more lower conductive layers, pins, or solder balls.

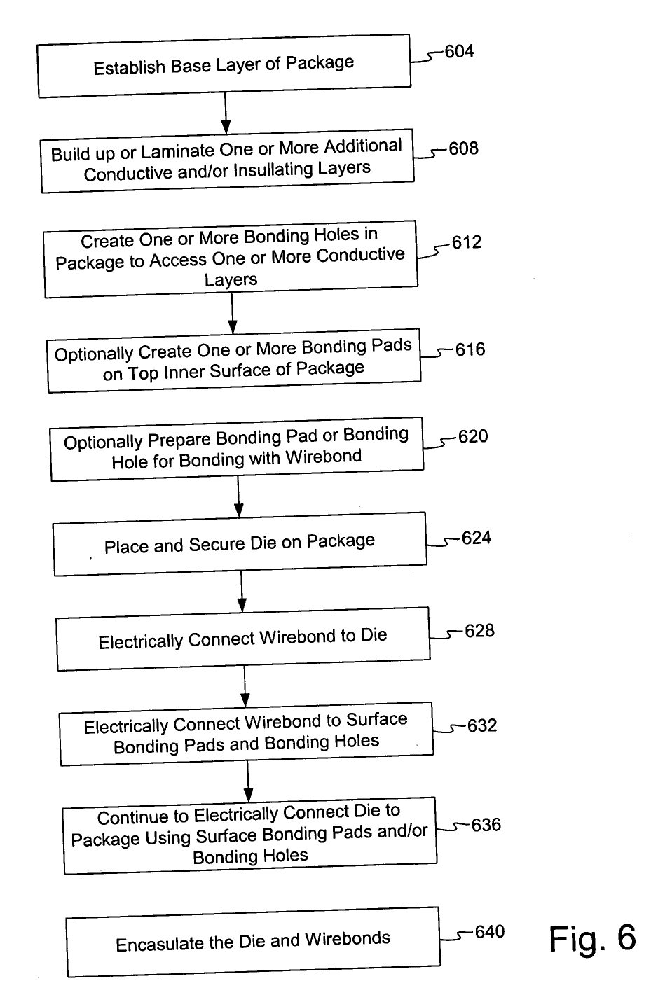

FIG. 6 is an operational flow diagram of an example method of package fabrication utilizing bonding holes. This is but one possible method of package fabrication and, as such, it is contemplated that one of ordinary skill in the art may arrive at other methods of fabrication without departing from the scope of the claims that follow. At a step 604, the method establishes a base layer of the package. In one embodiment, this layer serves as the foundation. Then, at a step 608, the fabrication process builds up or laminates one or more additional conductive and/or insulating layers to form the package base. The conductive layers may be utilized to electrically connect the die with external conductors associated with the package, such as solder balls of a ball grid array or more pins. It is contemplated that the layers may be intersected with holes or insulating dividers to thereby maintain electrical separation between the conductors and the signals conveyed thereon.

At a step 612, the fabrication process creates one or more bonding holes in the package to provide access to the one or more conductive layers of the package. It is contemplated that the bonding holes open to the top inner surface of the package and may be configured through one or more additional layers. The process for creating bonding holes may comprise any known process comprising, but not limited to, laser drilling, mechanical drilling, etching, and patterned additive layer formation.

At a step 616, the fabrication method may optionally create one or more bonding pads on the top inner surface of the package. These may be considered traditional type bonding pads, which are understood in the art. Thereafter, at a step 620, the fabrication may optionally prepare the bonding pads, the bonding holes, or both for bonding with a wirebond. This may comprise deposition of one or more layers on top of the bonding pad or in the bonding hole to facilitate the wirebond process.

At a step 624, the fabrication process places and secures a die on the package. Although shown in this operational flow diagram as occurring after the creation of the bonding holes, it is contemplated that the die may be placed on the package prior to creation of the bonding holes. In one embodiment, the die may be secured to the package with an epoxy. Thereafter, at a step 628, a wirebond is electrically connected to the die such as through a wirebonding process which utilizes pressure thermo-sonic energy, or both, to attach the wirebond wire to the bonding pad on the die. Then, at a step 632, the method collects the wirebond to the one or more surface bonding pads and the one or more bonding holes on the package. Due to the relatively small size of the wirebonding capillary in relation to the size of the bonding hole, the tip of the capillary is able to extend into the bonding hole to attach the wirebond into the bonding hole. It is contemplated that the wirebond may be manipulated to not touch the side of the hole if so desired.

At a step 636, the process of electrically connecting the die to the package continues until all of the desired electrical connections are established, i.e. by continuing to link bonding pads on the die with bonding pads or bonding holes associated with the package. Connection to a bonding hole may actually comprise bonding the wirebond to the bottom of the hole or via to thereby connect to a bonding pad or any conductor at the bottom or side of the hole, or to bond directly to the conductive layer exposed by the hole. Thereafter, at a step 640, the die is encapsulated to thereby cover and protect the die and the wirebonds.

Due to the use of bonding holes, the distance between the attachment points for the wirebonds, in relation to a radial distance from the die, may be reduced, thereby reducing the length of the wirebonds. This, in turn, reduces the cost of each device and reduces wire-sweep thereby increasing product yield. By connecting a wirebond through the bonding hole directly to a conductive layer or other conductor, it is not necessary to perform the additional step of extending a trace to a via, which electrically connects through an insulating layer to a conductive layer, solder ball, or pin.

While various embodiments of the invention have been described, it will be apparent to those of ordinary skill in the art that many more embodiments and implementations are possible that are within the scope of this invention.

1. A method for electrically connecting a die to a package comprising:
providing a package comprising a foundation and one or more laminated sections on the foundation to form a laminated package base, wherein a laminated section comprises an insulating layer covering a conductive layer and the package further comprises at least one bonding hole through at least one insulating layer to thereby expose a conductive layer;
securing a die to the package;
attaching a wirebond to at least one bonding pad on the die; and
attaching the wirebond to a conductive layer accessed through a bonding hole to thereby electrically connect the die to the package.

2. The method of claim 1, further comprising preparing the conductive layer, exposed by the bonding hole, for bonding with a wirebond.

3. The method of claim 1, wherein the wirebond comprises a gold wire.

4. The method of claim 1, wherein the package comprises at least one rows of surface bonding pads that radially surround the die and at least one row of bonding holes that radially surround the die whereby use of bonding holes allows for bonding directly to a conductive layer thereby reducing the length of at least one wirebond.

5. The method of claim 1, wherein attaching comprises thermo-sonic fusing.

6. A method for configuring a package for enclosing a die comprising:
providing a package foundation;
forming one or more conductive layers above the foundation;
forming one or more insulating layers above the foundation; and
creating one or more bonding holes in at least one insulating layer to provide access to at least one conductive layer, wherein the bonding hole is configured for placement of a wirebond there-through to bond directly to the conductive layer or a bonding pad on the conductive layer.

7. The method of claim 6, further comprising:
forming at least one bonding pad on the surface of the insulating layer;
forming a via to the conductive layer; and
forming a conductive trace between the via and the bonding pad on the surface of the insulating layer.

8. The method of claim 6, wherein the bonding hole is sized to accept a wirebond.

9. The method of claim 6, wherein creating a bonding hole comprises drilling using a laser.

10. The method of claim 6, wherein creating at least one bonding hole comprises forming at least one bonding hole through at least two insulating layers.

11. The method of claim 6, wherein one or more conductive layers and the one or more insulating layers alternate between conductive and insulating layers.

12. A package configured to electrically connect a die to a conductor external to the package comprising:
a package foundation having one or more conductive layers and one or more insulator layers;
one or more die placement locations configured to support a die;
one or more bonding holes located proximate to at least one of the one or more die placement locations, at least one bonding hole configured to extend through at least one insulating layer to thereby provide access to a conductive layer; and
at least one exterior conductor on the exterior of the package that is in electrical contact with at least one conductive layer.

13. The package of claim 12, further comprising a wirebond electrically connected to a die and a conductive layer accessed through one of the bonding holes.

14. The package of claim 12, wherein the package is configured as a multi-chip package configured to accommodate more than one die.

15. The package of claim 12, wherein the package comprises two insulator layers and the bonding hole passes through two insulator layers to expose a conductive layer.

16. The package of claim 12, further comprising a bonding pad at the bottom of a bonding hole, the bonding pad configured to accept a bond with a wirebond.

17. A semiconductor device comprising:
at least one die having one or more bonding pads configured to connect to one or more wirebonds;
a package comprising;
a package foundation;
one or more conductive layers;
one or more insulating layers, wherein at least one insulating layer covers at least one conductive layer;
one or more bonding holes through at least one insulating layer to thereby provide access to a conductive layer; and
at least one wirebond electrically connected to a bonding pad on the at least one die and to a conductive layer accessed through a bonding hole.

18. The device of claim 17, wherein the wirebond connects to a bonding pad prepared on the conductive layer that is accessed through the bonding hole.

19. The device of claim 18, wherein the bonding pad prepared on the conductive layer comprises a gold deposition.

20. The device of claim 17, further comprising:
one or more solder bumps or pins electrically accessible from the exterior of the package that are electrically connected to at least one of the one or more conductive layers; and
a protective layer formed to encapsulate the die and wirebonds.

21. The device of claim 17, wherein use of bonding holes reduces the length of at least one wirebond thereby reducing wire-sweep.
